(19) United States
(12) Patent Application Publication
(10) Pub. No.: US 2023/0099518 A1
(43) Pub. Date: Mar. 30, 2023

(54) CLASS-LABELED SPAN SEQUENCE IDENTIFYING APPARATUS, CLASS-LABELED SPAN SEQUENCE IDENTIFYING METHOD AND PROGRAM

(71) Applicant: NIPPON TELEGRAPH AND TELEPHONE CORPORATION, Tokyo (JP)

(72) Inventors: Tsutomu HIRAO, Tokyo (JP); Masaaki NAGATA, Tokyo (JP)

(21) Appl. No.: 17/908,487

(22) PCT Filed: Mar. 5, 2020
(86) PCT No.: PCT/JP2020/009302

§ 371 Date: Aug. 31, 2022

(51) Int. Cl. G06F 16/35; G06F 40/40; G06F 40/205

(52) U.S. Cl. CPC G06F 16/35; G06F 40/40; G06F 40/205

(57) ABSTRACT

A class-labeled span sequence identification apparatus includes a span generation unit that generates all spans generable from a unit sequence input, a calculation unit that calculates a probability that each of the spans belongs to an individual class of a plurality of predefined classes, and an identification unit that identifies, from among span sequences generable in accordance with the spans, a class-labeled span sequence having a maximum product of a plurality of the probabilities or a maximum sum of scores according to the plurality of the probabilities, and thereby, improves accuracy of a class segmentation position in the unit sequence.

### TECHNICAL FIELD

The present invention relates to a class-labeled span sequence identification apparatus, a class-labeled span sequence identification method, and a program.

### BACKGROUND ART

For convenience, a task of classifying each sentence in an article abstract (abstract of the article) into classes, such as “background,” “Method,” “result,” “conclusion,” will be described. However, these classes are provided for a chunk of sentences, rather than independently for a sentence. Because transitions between classes have definite limitations (for example, the background is not connected after the conclusion), the relevant task is treated as so-called a sequence labeling issue. That is, the relevant task is often treated as a sequence labeling task in which an individual sentence is assigned with a tag (B-B, B-M, B-R or B-C) meaning that the sentence is a start of the class, or a tag (I-B, I-M, I-R or I-C) meaning that the sentence is inside the class. For such a task, the BiLSTM-CRF model proposed in NPL 1 is currently used well.

### CITATION LIST

### Non Patent Literature

NPL 1: Huang, Z., Xu, W. and Yu, K., 2015. Bidirectional LSTM-CRF Models for Sequence Tagging, arXiv

### SUMMARY OF THE INVENTION

### Technical Problem

In using an existing sequence labeling, a sequence of class labels is captured with a tag of B-* or I-*, but eventually an individual unit (sentences) is assigned with the tag, and thus, even when accuracy of tagging is high, cutting out a unit sequence (e.g., a Background part) according to the tagging results may degrade an accuracy of a class segmentation position.

The present invention has been made in view of the above point and has an object to improve the accuracy of the class segmentation position in the unit sequence.

### Means for Solving the Problem

Thus, to solve the above issue, a class-labeled span sequence identification apparatus includes a span generation unit that generates all spans generable from a unit sequence input, a calculation unit that calculates a probability that each of the spans belongs to an individual class of a plurality of predefined classes, and an identification unit that identifies, from among span sequences generable in accordance with the spans, a class-labeled span sequence having a maximum product of a plurality of the probabilities or a maximum sum of scores according to the plurality of the probabilities.

### Effects of the Invention

This allows for improving the accuracy of the class segmentation position in the unit sequence.

### BRIEF DESCRIPTION OF DRAWINGS

FIG. 1 is a diagram illustrating a hardware configuration example of a class-labeled span sequence identification apparatus 10 according to an embodiment of the present invention.

FIG. 2 is a diagram illustrating a functional configuration example of the class-labeled span sequence identification apparatus 10 according to the embodiment of the present invention.

FIG. 3 is a diagram illustrating an example of a section segmentation of an article abstract.

FIG. 4 is a flowchart for explaining an example of a processing procedure of a parameter W learning process.

FIG. 5 is a flowchart for explaining an example of a processing procedure of an optimal class-labeled span sequence identifying process.

### DESCRIPTION OF EMBODIMENTS

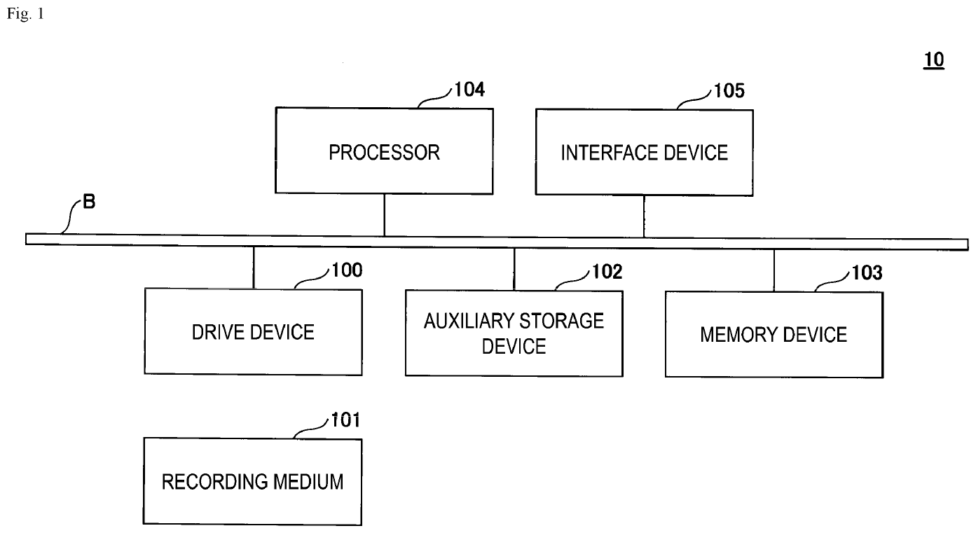

Hereinafter, embodiments of the present disclosure will be described with reference to the drawings. FIG. 1 is a diagram illustrating a hardware configuration example of a class-labeled span sequence identification apparatus 10 according to an embodiment of the present invention. The class-labeled span sequence identification apparatus 10 in FIG. 1 includes a drive device 100, an auxiliary storage device 102, a memory device 103, a processor 104, an interface device 105, and the like which are connected to each other via a bus B.

A program for implementing processing in the class-labeled span sequence identification apparatus 10 is provided by a recording medium 101 such as a CD-ROM. When the recording medium 101 storing the program is set in the drive device 100, the program is installed on the auxiliary storage device 102 from the recording medium 101 via the drive device 100. However, the program does not necessarily have to be installed from the recording medium 101 and may be downloaded from another computer via a network. The auxiliary storage device 102 stores the installed program and also stores files, data, and the like.

The memory device 103 reads and stores the program from the auxiliary storage device 102 when the program is instructed to start. The processor 104 is, for example, a CPU, a Graphics Processing Unit (GPU), or the like, and performs functions related to the class-labeled span sequence identification apparatus 10 in accordance with programs stored in the memory device 103. The interface device 105 is used as an interface for connection to a network.

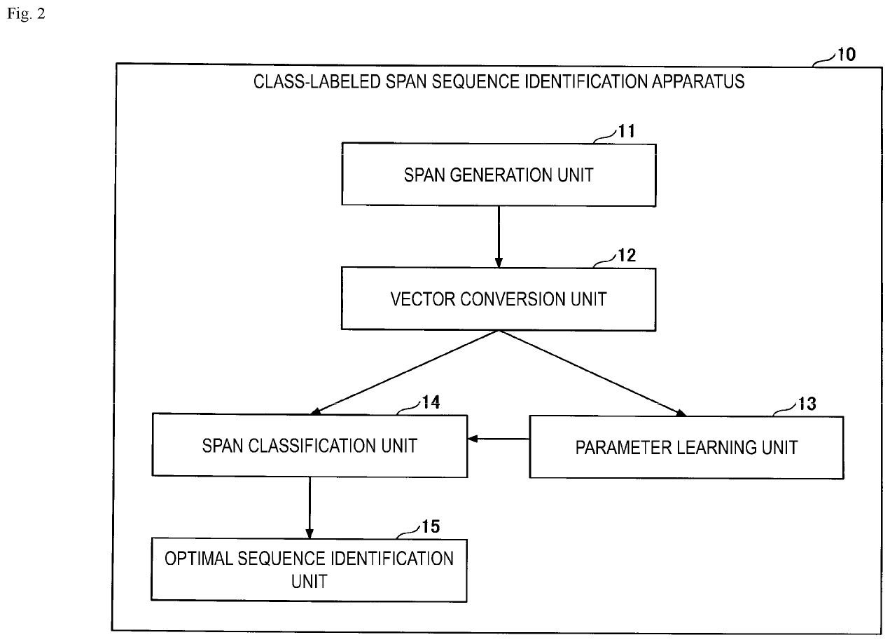

FIG. 2 is a diagram illustrating a functional configuration example of the class-labeled span sequence identification apparatus 10 according to the embodiment of the present invention. In FIG. 2, the class-labeled span sequence identification apparatus 10 includes a span generation unit 11, a vector conversion unit 12, a parameter learning unit 13, a span classification unit 14, an optimal sequence identification unit 15, and the like, receives sequence data of a unit (hereinafter, referred to as a “unit sequence”) as input, and outputs a class-labeled span sequence. These units are implemented by processes which one or more programs installed in the class-labeled span sequence identification apparatus 10 cause the processor 104 to execute. Note that each unit is implemented by a neural network, and represents a part of an End-to-End model. The class-labeled span sequence refers to a span sequence assigned with a label indicating a class. The unit is, for example, a sentence. However, the unit may be obtained by segmenting a sentence in predetermined units, such as a paragraph, a clause, and a word.

The span generation unit 11 generates all spans generable from a unit sequence input, and outputs the generated spans to the vector conversion unit 12. Assuming a length of a certain unit sequence (number of units) is n, the generable spans include s(1, 1), s(1, 2), . . . , s(1, n), s (2, 2), . . . , s(2, n), s(n−1, n−1), s(n−1, n), s(n, n), in other words, n(n+1)/2 spans are generated. Note that s(a, b) represents a span constituted by the a-th to b-th continuous units. Note that in a case that there is some constraint, the span generation unit 11 may generate a span with the constraint taken into account. The some constraint is, for example, that a span starting from the first unit is not generated, that a span having a length of 1 is not generated, or the like.

The vector conversion unit 12 converts each of the spans generated by the span generation unit 11 into a vector, and outputs the converted vector to the parameter learning unit 13 or the span classification unit 14. In a case that learning of the parameters is performed by the parameter learning unit 13, each vector resulting from the conversion is output to the parameter learning unit 13. In a case that the learning of the parameters by the parameter learning unit 13 has been performed, each vector resulting from the conversion is output to the span classification unit 14.

Note that in the case that the learning of the parameters is performed by the parameter learning unit 13, a set D of learning data pieces is input to the span generation unit 11, and a span is generated for each learning data piece. Elements (each learning data piece) constituting the set D are a plurality of unit sequences.

Here, a vector representation of the i-th unit in the d-th learning data piece (unit sequence) of the set D is defined as u^{d}ᵢ. As the vector representation, a word embedding vector representation is used if the unit is a word, or a sentence embedding vector representation based on the word embedding is used if the unit is a sentence. Next, a forward Long short-term memory (LSTM) in a bidirectional LSTM is expressed as below.

FUNCTION \vec{LSTM} [Math. 1]

A backward LSTM is expressed as below.

FUNCTION [symbol] [Math. 2]

These expressions are used to define a vector obtained from the forward LSTM of the i-th unit in the d-th data piece as below.

[Math. 3]

fᵢ^{d}=\vec{LSTM}(fᵢ₋₁,uᵢ^{d}) (1)

A vector obtained from the backward LSTM of the i-th unit in the d-th data piece is defined as below.

[Math. 4]

bᵢ^{d}= [symbol] (b₊₁,uᵢ^{d}) (2)

A vector representation of a span (hereinafter, referred to as a “span vector”) from the i-th unit to the j-th unit in the d-th data piece is defined as below.

[Math. 5]

s_{i:j}^{d}=[fⱼ^{d}−fᵢ₋₁^{d};bᵢ₋₁^{d}−bⱼ^{d}] (3)

Thus, for each learning data piece, the vector conversion unit 12 converts all of the spans generated for each learning data piece into span vectors in accordance with Equations (1) to (3) above.

The span classification unit 14 receives the span vector, calculates a score (probability) that each span belongs to each of the predefined classes by using a parameter matrix obtained from the parameter learning unit 13, and outputs the calculation result to the optimal sequence identification unit 15.

Specifically, the span classification unit 14 calculates, for each of all the span vectors, a score (probability) that the span vector belongs to each class by using the following equation.

[Math. 6]

P(s_{i:j}^{d}, [symbol] )=softmax(W·s_{i:j}^{d}^{^{T}}) (4)

L represents a set of class labels, and W represents a matrix that stores a parameter of |L|×len(s^{d}_{i:j}) (number of classes x dimension number of s^{d}_{i:j}). softmax represents a function to normalize the score to a value of [0, 1]. The probability that the span vector s^{d}_{i:j} belongs to the k-th class lₖ (ϵL) is defined by the following equation by using an inner product of the k-th row vector W_{k:*} of W and the span vector s^{d}_{i:j}.

$$\begin{matrix}[ Math . 7 ] & \\ P ( {s}_{i : j}^{d} , {ℓ}_{k} ) = \frac{exp ( {W}_{k : *} \cdot {s}_{i : j}^{d} )}{{\sum }_{k = 1}^{\vert ℒ \vert} exp ( {W}_{k : *} \cdot {s}_{i : j}^{d} )} & ( 5 )\end{matrix}$$

Note that W is learned by the parameter learning unit 13 in advance.

The parameter learning unit 13 learns the parameter W that minimizes a cross entropy loss below.

$$\begin{matrix}[ Math . 8 ] & \\ E ( W ) = - {\sum }_{d = 1}^{\vert D \vert} {\sum }_{k = 1}^{\vert ℒ \vert} {y}_{k}^{d} log {\hat{y}}_{k}^{d} & ( 6 )\end{matrix}$$

y^{d}ₖ represents a binary vector indicating a correct class label for the k-th unit in the d-th data piece of the set D, and is preset as learning data. In the vector, for y^{d}ₖ, the element lₖ is 1 and the other is 0. y\hat{ }^{d}ₖ (where y\hat{ } corresponds to ϵ of \hat{ } above y in Equation (6)) is the probability estimated using Equation (5). W can be optimized using a gradient method. In other words, the parameter learning unit 13 randomly initializes W, and uses this W to determine y\hat{ }^{d}ₖ=P(s^{d}_{i:j},lₖ) by using Equation (5). The parameter learning unit 13 applies the result to Equation (6) to calculate the cross entropy loss. The parameter learning unit 13 repeats the procedure of updating W so as to reduce the loss.

The optimal sequence identification unit 15 receives the all spans and the probability that each span belongs to each class, for (segmentations of) all the spans output from the span classification unit 14, and identifies one optimal class-labeled span sequence. First, a lattice that stores all possible span sequences is considered, and a span sequence that a product of the probabilities or a sum of the scores referring to the probabilities (sum of log(P)) is maximum is identified as the optimal class labeled span sequence from a path in the lattice. A maximum value of the score until s(i, j) is a maximum value of the score for s(*, i−1) plus the maximum score of s(i, j).

For example, assume that a unit sequence constituted by five units is provided. In this case, all the spans are (1,1), (1,2), . . . , (5,5), and a span sequence generable in accordance with these spans is, for example, (1,1)→(2,3)→(4,4)→(5,5), (1,2)→(3,4)→(5,5), or the like. In other words, a span that can be connected to one before any span is only a span that ends at its starting position−1, and the other spans are excluded from candidate solutions.

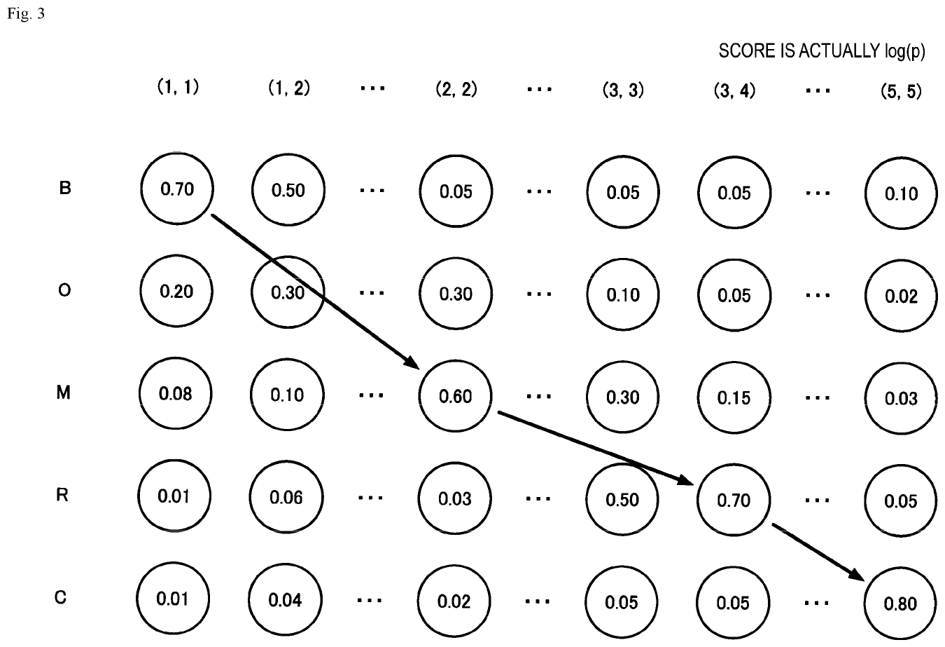

FIG. 3 is a diagram illustrating an example of a section segmentation of an article abstract. In FIG. 3, an example is illustrated where the span is classified into any class of B, O, M, R, and C. Referring to FIG. 3, the maximum score until any state (each circle in FIG. 3) is determined by adding the maximum score of the current state to the maximum score of a state one before the current state. For example, the maximum score until s(3, 4) is obtained by adding the maximum score log(0.7) for s(3, 4) to the maximum score until s(*, 2).

In this way, it is possible to obtain the span sequence that the score is maximum from among all of the span sequences by recursively repeating adding the maximum score of the current state to the maximum score of the state one before the current state. Note that in order to output the class-labeled span sequence, the optimal sequence identification unit 15 stores a class label for a state that gives the maximum score in each state. In FIG. 3, those are B for (1,1), M for (2,2), R for (3,4), and C for (5,5), which results in a final output (i.e., the optimal class-labeled span sequence).

This procedure is the Viterbi algorithm itself. Note that only the score of the state is considered in FIG. 3, but a score can be provided for a transition between the states.

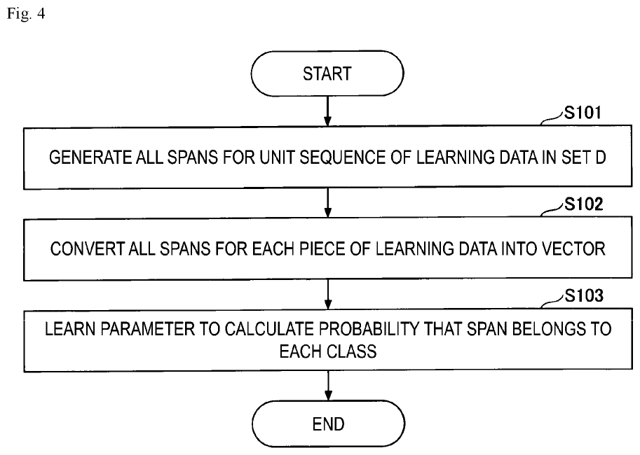

Hereinafter, a processing procedure executed by the class-labeled span sequence identification apparatus 10 will be described. FIG. 4 is a flowchart for explaining an example of a processing procedure of a parameter W learning process.

In step S101, the span generation unit 11 generates (the segmentations of) all the spans generable from the unit sequence for each piece of the leaning data d (unit sequence) included in the set D of learning data pieces, and outputs the generated spans to the vector conversion unit 12.

Subsequently, the vector conversion unit 12 converts each of the spans generated by the span generation unit 11 for each piece of the learning data d into a vector, and outputs the vector resulting from the conversion to the parameter learning unit 13 (S102).

Subsequently, the parameter learning unit 13 learns the parameter W in accordance with Equations (6) and (5) by referring to the relevant vector and y^{d}ₖ preset for each unit k of each piece of the learning data d (S103). The learned parameter W is stored, for example, in the auxiliary storage device 102.

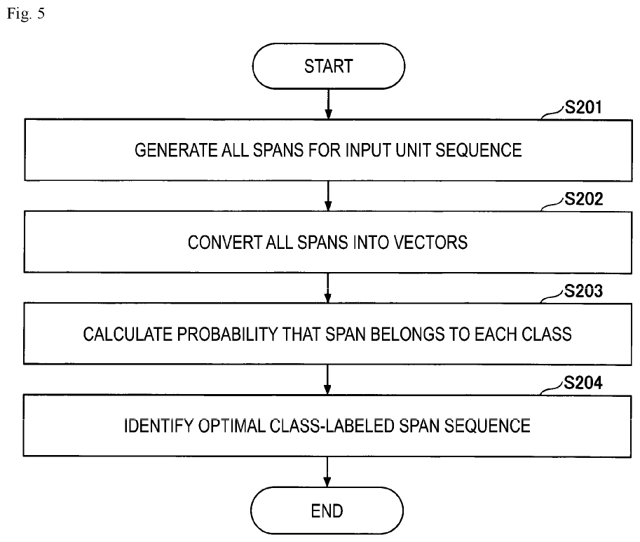

FIG. 5 is a flowchart for explaining an example of a processing procedure of an optimal class-labeled span sequence identifying process.

In step S201, the span generation unit 11 generates all the spans generable for the unit sequence input (hereinafter, referred to as “input sequence”), and outputs the generated spans to the vector conversion unit 12.

Subsequently, the vector conversion unit 12 converts each of the spans generated by the span generation unit 11 into a vector in accordance with Equations (1) to (3), and outputs the vector resulting from the conversion to the span classification unit 14 (S202).

Subsequently, the span classification unit 14 applies the relevant vector and the learned parameter W stored in the auxiliary storage device 102 to Equation (5), for example, to calculate the score (probability) that each span belonging to each class, and outputs the calculation result to the optimal sequence identification unit 15 (S203).

Subsequently, the optimal sequence identification unit 15 identifies the optimal class-labeled span sequence by referring to the score (probability) according to the method described above (S204).

Note that, the above description is given using the article abstract as an example of the unit sequence, but the present embodiment can be applied to any sequence labeling as long as there is a constraint on the transitions between classes.

As described above, according to the present embodiment, rather than assigning the tag to the unit, all possible subsequences (hereinafter, spans) are extracted from the unit sequence, and the class label is directly assigned to the span, so that the sequence labeling is performed. As a result, the determination performance and classification performance of the span can be improved. In other words, it is possible to improve the accuracy of the class segmentation position in the unit sequence.

Note that, in the present embodiment, the span classification unit 14 is an example of a calculation unit. The optimal sequence identification unit 15 is an example of an identification unit.

Although the embodiments of the present disclosure have been described in detail above, the present disclosure is not limited to such specific embodiments, and various modifications and change can be made within the scope of the gist of the present disclosure described in the aspects.

### REFERENCE SIGNS LIST

10 Class-labeled span sequence identification apparatus
11 Span generation unit
12 Vector conversion unit
13 Parameter learning unit
14 Span classification unit
15 Optimal sequence identification unit
100 Drive device
101 Recording medium
102 Auxiliary storage device
103 Memory device
104 Processor
105 Interface device
B Bus

1. A class-labeled span sequence identification apparatus comprising a processor configured to execute a method comprising:
generating a plurality of spans from a unit sequence input, wherein each span corresponds to a part of a unit in the unit sequence input;
calculating a probability that each of the plurality of spans belongs to an individual class of a plurality of predefined classes; and
identifying, from among span sequences generable in accordance with the plurality of spans, a class-labeled span sequence having either one of a maximum product of a plurality of probabilities including the probability or a maximum sum of scores according to the plurality of the probabilities.

2. The class-labeled span sequence identification apparatus according to claim 1, wherein
the identifying further comprises identifying the class-labeled span sequence by using a Viterbi algorithm.

3. A computer implemented method for identifying a class-labeled span sequence, comprising:
generating a plurality of spans based on a unit sequence input, wherein each span corresponds to a part of a unit in the unit sequence input;
calculating a probability that each of the plurality of spans belongs to an individual class of a plurality of predefined classes; and
identifying, from among span sequences generable in accordance with the plurality of spans, a class-labeled span sequence having either one of a maximum product of a plurality of probabilities including the probability or a maximum sum of scores according to the plurality of the probabilities.

4. A computer-readable non-transitory recording medium storing computer-executable program instructions that when executed by a processor cause a computer to execute a method for identifying a class-labeled span sequence, comprising:
generating a plurality of spans based on a unit sequence input, wherein each span corresponds to a part of a unit in the unit sequence input;
calculating a probability that each of the plurality of spans belongs to an individual class of a plurality of predefined classes; and
identifying, from among span sequences generable in accordance with the plurality of spans, a class-labeled span sequence having either one of a maximum product of a plurality of probabilities including the probability or a maximum sum of scores according to the plurality of the probabilities.

5. The class-labeled span sequence identification apparatus according to claim 1, wherein the unit includes a part of a document, the part corresponds to at least one of:
a paragraph,
a sentence,
a phrase, or
a word.

6. The class-labeled span sequence identification apparatus according to claim 1, wherein a span corresponds to a set of a contiguous sequence of a plurality of units.

7. The class-labeled span sequence identification apparatus according to claim 1, wherein the plurality of spans is according to a constraint, the constraint includes excluding a set of a contiguous sequence of a plurality of units starting at a first unit in a sequence of the plurality of units.

8. The class-labeled span sequence identification apparatus according to claim 1, wherein the individual class includes at least one of:
background section of an article,
method section of the article,
result section of the article, or
conclusion section of the article.

9. The class-labeled span sequence identification apparatus according to claim 1, wherein the class-labeled span sequence corresponds to a sequence of spans, each span of the plurality of spans is associated with a label indicating the individual class.

10. The class-labeled span sequence identification apparatus according to claim 1, the processor further configured to execute a method comprising:
generating all spans generable from the unit sequence input.

11. The computer implemented method according to claim 3, wherein
the identifying further comprises identifying the class-labeled span sequence by using a Viterbi algorithm.

12. The computer implemented method according to claim 3, wherein the unit includes a part of a document, the part corresponds to at least one of:
a paragraph,
a sentence,
a phrase, or
a word.

13. The computer implemented method according to claim 3,
wherein a span corresponds to a set of a contiguous sequence of a plurality of units, and wherein the class-labeled span sequence corresponds to a sequence of spans, each span of the plurality of spans is associated with a label indicating the individual class.

14. The computer implemented method according to claim 3, wherein the plurality of spans is according to a constraint, the constraint includes excluding a set of a contiguous sequence of a plurality of units starting at a first unit in a sequence of the plurality of units.

15. The computer implemented method according to claim 3, wherein the individual class includes at least one of:
background section of an article,
method section of the article,
result section of the article, or
conclusion section of the article.

16. The computer implemented method according to claim 3, further comprising:
generating all spans generable from the unit sequence input.

17. The computer-readable non-transitory recording medium according to claim 4, wherein
the identifying further comprises identifying the class-labeled span sequence by using a Viterbi algorithm.

18. The computer-readable non-transitory recording medium according to claim 4, wherein the unit includes a part of a document, the part corresponds to one of:
a paragraph,
a sentence,
a phrase, or
a word, and
wherein the individual class includes at least one of:
background section of an article,
method section of the article,
result section of the article, or
conclusion section of the article.

19. The computer-readable non-transitory recording medium according to claim 4, wherein a span corresponds to a set of a contiguous sequence of a plurality of units, and wherein the class-labeled span sequence corresponds to a sequence of spans, each span of the plurality of spans is associated with a label indicating the individual class.

20. The computer-readable non-transitory recording medium according to claim 4, the computer-executable program instructions when executed further causing the computer to execute a method comprising:
generating all spans generable from the unit sequence input.
